(19) United States
(12) Patent Application Publication
(10) Pub. No.: US 2002/0063324 A1
(43) Pub. Date: May 30, 2002

(54) Semiconductor device, method of fabricating same, semiconductor device package construction, and method of mounting the semiconductor device

(75) Inventor: Toshinori Shiina, Tokyo (JP)

Correspondence Address: Paul J. Esatto, Jr., Scully, Scott, Murphy & Presser, 400 Garden City Plaza, Garden City, NY, 11530, US

(73) Assignee: NEC Corporation, Tokyo (JP)

(21) Appl. No.: 09/994,957

(22) Filed: Nov. 27, 2001

(30) Foreign Application Priority Data
Nov. 30, 2000 (JP) 2000-366231

(51) Int. Cl. H01L 23/02

(52) U.S. Cl. 257/690; 257/678

(57) ABSTRACT

A semiconductor device allows for mounting by means of low load in a flip-chip mounting method, enables prevention of damage, enables an increase in the reliability of electrical connections in a high-temperature environment, and further, enables the efficient fabrication of miniaturized external connection electrodes. In semiconductor device 1, miniaturized external connection electrodes 12 are formed by lamination on electrodes of semiconductor chip 11, and these external connection electrodes electrically connect by means of contact with substrate wiring 21 while maintaining an elastically deformed state. The semiconductor device may further include elastic layer 13, bumps 14, and protective film 15.

### BACKGROUND OF THE INVENTION

1. Field of the Invention

The present invention relates to a semiconductor device, a method of fabricating the semiconductor device, a semiconductor device package construction, and the method of mounting the semiconductor device; and more particularly to a semiconductor device in a flip-chip mounting mode that both improves the reliability of connection of external connection electrodes and allows for miniaturization of the external connection electrodes, a method of fabricating such a semiconductor device, a semiconductor device package construction, and a method of mounting the semiconductor device.

2. Description of the Related Art

A flip-chip mounting method is a method in which a semiconductor device having protruding electrodes (external connection electrodes) that have been formed on the electrodes of a semiconductor chip surface is arranged face-down with respect to a mounting body (for example, a circuit substrate) such that the protruding electrodes electrically connect to electrodes (land electrodes) of the mounting body.

This flip-chip mounting method enables an increase in the number of pins of the semiconductor device, miniaturization of the semiconductor device, and higher-density packaging of semiconductor devices, and as a result, extensive research and development is being carried out by makers of semiconductor device and a wide variety of techniques have been disclosed regarding for example, the shape of the protruding electrodes and methods of establishing connection between electrodes.

With regard to packaging density, and in particular, miniaturization of external connection electrodes, semiconductor devices in which the pitch of the external connection electrodes is approximately 100 μm are coming into practical use.

(Prior Art)

Japanese Patent Laid-open No. 262430/85 discloses a technique for electrically connecting the external connection electrodes of a semiconductor device to substrate electrodes by means of the force of contraction of the resin that bonds the semiconductor device to the substrate.

We refer now to the accompanying figures to describe this technique.

FIG. 1 shows a schematic view for explaining a semiconductor device of an example of the prior art and the method of mounting the semiconductor device, FIG. 1(a) showing a sectional view before mounting and FIG. 1(b) showing a sectional view after mounting.

Referring now to FIG. 1(a), regarding semiconductor device 110, metal electrodes 111 are formed as external connection electrodes on the-electrodes of the semiconductor chip surface (not shown in the figure); and regarding substrate 130, substrate wiring 131 is formed as land electrodes for connection at positions corresponding to metal electrodes 111, and further, bonding resin 120 for bonding semiconductor device 110 is applied to substrate 130.

Bonding resin 120 may be an ultraviolet ray curing or a thermosetting type of resin.

In FIG. 1(b), semiconductor device 110 is aligned such that metal electrodes 111 formed on bumps contact substrate wiring 131, and the facedown arrangement presses metal electrodes 111 against substrate wiring 131 to establish electrical connection.

Even if bonding resin 120 should remain between metal electrodes 111 and substrate wiring 131 when semiconductor device 11 is arranged facedown, bonding resin 120 is squeezed out when metal electrodes 111 are pressed against substrate wiring 131 and metal electrodes 111 can thus make electrical contact with substrate wiring 131.

When bonding resin 120 is cured by heat or ultraviolet rays with semiconductor device 110 in a state such that metal electrodes 111 are pressed against substrate wiring 131, bonding resin 120 shrinks, and the force of this shrinkage is able to maintain the electrical contact between metal electrodes 111 and substrate wiring 131.

Nevertheless, due to some variation that typically occurs in the height of metal electrodes 111 as shown by dimension C and dimension D in FIG. 1(a), metal electrodes 111 are pressed against substrate wiring 131 by a large external force (load) when mounting to cause plastic deformation of metal electrodes 111 and even the height of meal electrodes 111, thereby ensuring electrical contact between all metal electrodes 111 and substrate wiring 131. However, this pressure results in the problem of a potential for damage to semiconductor device 110 and substrate wiring 131.

In addition, semiconductor device 110 is bonded to substrate 130 by bonding resin 120, and when semiconductor device 110 undergoes an increase in temperature when, for example, conducting electricity, this rise in temperature causes thermal expansion of bonding resin 120, and the problem therefore occurs that metal electrodes 111 separate from substrate wiring 131 and the electrical connection is disrupted when the difference between the amount of expansion of bonding resin 120 and the amount of expansion of metal electrodes exceeds the sum of the amount of shrinkage of bonding resin 120 when cured and the elastic displacement that is stored in metal electrodes 111.

Still further, the extremely small elastic displacement of metal electrodes 111 of semiconductor device 110 results in the additional problem that when an acceleration test such as a temperature cyclic test is carried out, the electrical connection between metal electrodes 111 and substrate wiring 131 becomes unstable and connection reliability is lost.

The problem regarding electrical connection that results from differing linear expansion coefficients can be solved by adding silica to, or increasing the amount of silica in, bonding resin 120 to make the linear expansion coefficient of bonding resin 120 lower than the linear expansion coefficient of metal, or by increasing the elastic displacement stored in metal electrodes 111. However, the addition of silica increases the Young's modulus of bonding resin 120 and thus places a heavy load on the semiconductor device and substrate when bonding resin 120 undergoes thermal expansion. This load results in an increase in the danger of damage to semiconductor device 110 or substrate 130, and the simple addition of silica therefore is not possible.

In addition, the form of the metal electrodes of the prior art is normally nodular, such as a sphere or cylinder, and the elastic displacement of the metal electrodes is therefore difficult to increase.

Referring now to the accompanying figures, further explanation is given regarding the difficulty of increasing the elastic displacement of the metal electrodes.

FIG. 2 is a graph that gives a schematic representation of the relation between displacement and load on the metal electrodes when mounting a semiconductor device by a method of the prior art.

In this figure, the application of external force upon metal electrodes having a high profile such that metal electrodes having a low profile contact substrate wiring 131 causes the metal electrodes having high profile to undergo plastic deformation, this deformation typically being displacement OF (displacement from O to point F).

In this case, the displacement OF of the metal electrodes is composed of displacement OG of plastic displacement and displacement GF of elastic displacement, the greater portion of the deformation of the metal electrodes being plastic deformation and the proportion due to elastic deformation being relatively small.

In actual practice, elastic displacement is difficult to increase because the stored elastic displacement (displacement GF) of the nodular metal electrodes is largely determined by the metal material that is used, and the metal materials that can be employed as electrodes are limited.

Since the demands for smaller, lighter, and cheaper devices must be met, there is the further problem that the semiconductor device must allow for efficient manufacture of miniaturized external connection electrodes even when the pitch of the external connection electrodes is less than approximately 100 μm.

### SUMMARY OF THE INVENTION

The present invention was realized with the purpose of solving the above-described problems and has as an object the provision of: a semiconductor device that allows mounting in a flip-chip mounting mode with low load to prevent the occurrence of damage, that can raise the reliability of electrical connections in a high-temperature environment, and further, that enables the efficient fabrication of miniaturized external connection electrodes; a method of fabricating such a device; a semiconductor device package construction, and a mounting method.

As an example of a technique that is relevant to the above-described problems, a semiconductor integrated circuit device is disclosed in Japanese Patent Laid-open No. 37233/94 that enables high-density packaging through the use of leads that extend toward the inside of the semiconductor device and that have a bent portion that is formed in the space between the chip and the substrate that absorbs and dampens stress arising from the difference between the linear expansion coefficients of the semiconductor chip and the substrate.

Although this example of the prior art can absorb and dampen stress that arises from the difference in linear expansion coefficients, this prior art suffers from several problems. Not only is accurate bending of the leads problematic, but the formation of rubber elastic bodies between the leads and the semiconductor chip surface further complicates the construction and lowers yield, and, in addition, complicates the miniaturization of leads when attempting high-density packaging. This example of the prior art is therefore unable to solve the above-described problems.

To achieve the above-described objects, the semiconductor device described in claim 1 of the present invention includes: a semiconductor chip on which electrodes have been formed; and external connection electrodes that are electrically connected to land electrodes of a mounting body; wherein the external connection electrodes are constructed to contact the land electrodes while maintaining an elastically deformed state.

By means of this construction, the external connection electrodes store a large elastic displacement and the external connection electrodes and the land electrodes of the mounting body can therefore maintain contact when the temperature of a mounted semiconductor device rises due to the conduction of electricity and the bonding resin thermally expands, and as a result, the reliability of electrical connection can be improved.

The invention of claim 2 is a construction in which the external connection electrodes in the semiconductor device described in the above-described claim 1 are laminated on the electrodes of a semiconductor chip.

By means of this construction, the external connection electrodes are amenable to miniaturization, and further, can be efficiently fabricated with good dimensional accuracy and at low cost.

The invention of claim 3 is a construction in which the side surfaces of the external connection electrodes in the semiconductor device according to the above-described claim 1 have an L-shape.

By means of this construction, the external connection electrodes can store a large elastic displacement with respect to upward or downward displacement. In other words, the bending of the external connection electrodes when mounting a semiconductor device can absorb variations in the coplanarity of each external connection electrode or land electrode, thereby enabling a reduction of the external force used to press the semiconductor device against the mounting body and enabling the elimination of the danger of damage to the semiconductor device and mounting body.

The invention described in claim 4 is a construction in which the shape of the upper surface of the external connection electrodes in the semiconductor device according to the above-described claim 1 has a bent portion.

By means of this construction, the external connection electrodes can store a large elastic displacement with respect to horizontal displacement.

The invention described in claim 5 is a construction in which bumps are formed on the external connection electrodes in the semiconductor device according to the above-described claim 1.

By means of this construction, bumps can be formed on the external connection electrodes for cases in which the formation of bumps on the land electrodes of a mounting body is problematic from the viewpoint of productivity.

The invention described in claim 6 is a construction in which an elastic layer is formed between the external connection electrodes and the semiconductor chip in the semiconductor device according to above-described claim 1.

By means of this construction, the external connection electrodes contact an elastic layer when being deformed in an upward direction, and the elastic force of the elastic layer is added to the elastic force of the external connection electrodes, thereby enabling adjustment of the load and amount of elastic deformation that is stored in the external connection electrodes when mounting the semiconductor device.

The invention described in claim 7 is a construction in which a protective film having an insulative property is formed on the lower surface of the external connection electrodes in the semiconductor device according to the above-described claim 1.

By means of this construction, external connection electrodes do not directly contact the wiring of a mounting body, thereby preventing the occurrence of short-circuit defects and enabling easy and high-quality packaging.

Forming the protective film from an elastic material, moreover, reduces the area in which the external connection electrodes contact the bonding resin and thus can eliminate a main cause of interference of the elastic deformation of the external connection electrodes.

Still further, the protective film can be used as a spacer that determines the position in the direction of height of the semiconductor device and mounting body, and the elastic displacement of the external connection electrodes can be set as appropriate.

The invention described in claim 8 is a construction in which the external connection electrodes are arranged as an array in the semiconductor device according to the above-described claim 1.

This construction allows the external connection electrodes to be arranged in an array of, for example, n×m rows (where n and m are natural numbers), thereby enabling application to greater numbers of pins.

The invention described in claim 9 is a construction in which a portion or all of the plurality of external connection electrodes in the semiconductor device according to the above-described claim 1 extend either toward the inside or toward the outside of the semiconductor chip.

This construction can increase the degree of freedom when designing the arrangement of land electrodes on the mounting body, and as a result, can realize high-density packaging of a semiconductor device.

The method of fabricating a semiconductor device according to claim 10 in the present invention comprises steps of: forming electrodes on a semiconductor chip; and forming, on electrodes of the semiconductor chip, external connection electrodes that electrically connect to land electrodes of a mounting body on which the semiconductor device is mounted, the external connection electrodes establishing electrical connection by contact while maintaining an elastically deformed state. In addition, the invention according to claim 11 is a method in which the step of forming external connection electrodes on the electrodes of the semiconductor chip in the method of fabricating a semiconductor device according to the above-described claim 10 is a step of forming external connection electrodes by lamination on the electrodes of a semiconductor chip.

This method enables the efficient production of miniaturized external connection electrodes with good dimensional accuracy.

The invention according to claim 12 is a method in which the step of forming the external connection electrodes on the electrodes of the semiconductor chip in the method of fabricating a semiconductor device according to the above-described claim 10 includes steps of: forming the external connection electrodes by lamination on a mask of the semiconductor chip, and electrically connecting the external connection electrodes with the electrodes of the semiconductor chip by way of a conductive material.

This method enables the efficient production of miniaturized external connection electrodes with good dimensional accuracy, and moreover, enables easy exchange of semiconductor chips.

The package construction of a semiconductor device according to claim 13 of the present invention is a construction that includes: a mounting body on which land electrodes are formed; a semiconductor device that includes external connection electrodes that are formed by lamination on a semiconductor chip and that contact the land electrodes while maintaining an elastically deformed state; and bonding resin for bonding the semiconductor device to the mounting body.

This construction can secure the semiconductor device to the mounting body by the bonding resin, can eliminate the danger of damage to the semiconductor device and the mounting body through the use of the elastically deformed external connection electrodes, and moreover, can raise the reliability of the electrical connections.

The invention according to claim 14 is a construction in which bumps are formed on either the land electrodes or the external connection electrodes, in the package construction of a semiconductor device according to the above-described claim 13.

This construction allows the formation of the external connection electrodes by lamination in a horizontal direction, thereby eliminating the need to laminate inclined external connection electrodes and thus improving productivity.

The invention according to claim 15 is a construction in which a spacer for positioning in the direction of height of the semiconductor chip is provided between the semiconductor chip and the mounting body in the semiconductor device package construction according to the above-described claim 13.

This construction enables easy and accurate positioning in the direction of height of the semiconductor device, thereby enabling adjustment of the elastic displacement of the external connection electrodes.

The method of mounting a semiconductor device according to claim 16 of the present invention is a method including steps of: supplying in advance, to a mounting body having land electrodes and/or a semiconductor device having external connection electrodes, a bonding resin for bonding the semiconductor device to the mounting body; and curing the bonding resin such that the external connection electrodes contact the land electrodes while maintaining an elastically deformed state.

This method enables elastic displacement of the external connection electrodes with low load and further, enables connection of the external connection electrodes and land electrodes in this state, thereby enabling both the elimination of the danger of damage to the semiconductor device and the mounting device and an improvement of the reliability of electrical connection.

The invention according to claim 17 is a method that employs the force of contraction when the bonding resin is cured to maintain elastic deformation in the semiconductor device mounting method according to the above-described claim 16.

This method can reduce the size of the pressing apparatus for pressing the semiconductor device against the mounting body, and further, can reduce the cost of the pressing apparatus.

As described in the foregoing explanation, according to the semiconductor device, the method of fabricating the semiconductor device, the package construction of the semiconductor device, and the mounting method of the present invention, forming external connection electrodes by lamination that can store large elastic displacement on a semiconductor device allows the absorption, under low load, of variations in the height of the external connection electrodes or bumps when mounting, and thus can eliminate the danger of damage to the substrate and semiconductor device, and further, can obtain good electrical connection despite displacement between the electrodes of the semiconductor chip and the land electrodes that accompanies changes in temperature after mounting. In addition, because formation by lamination is possible even in the case of miniaturized external connection electrodes, the invention is amenable to more compact semiconductor devices, a greater number of pins, and higher packaging density. The above and other objects, features, and advantages of the present invention will become apparent from the following description based on the accompanying drawings, which illustrate examples of preferred embodiments of the present invention.

### BRIEF DESCRIPTION OF THE DRAWINGS

FIG. 1 is a schematic representation for explaining a semiconductor device and a method of mounting the semiconductor device in an example of the prior art, FIG. 1(a) being a sectional view before mounting, and FIG. 1(b) being a sectional view after mounting.

FIG. 2 is a graph giving a schematic representation of the relation between displacement and load in metal electrodes when mounting a semiconductor device according to the prior art.

FIG. 3 shows enlarged schematic views for explaining an embodiment of a semiconductor device according to the present invention, FIG. 3(a) showing a sectional view, FIG. 3(b) showing an external view of external connection electrodes, FIG. 3(c) showing a sectional view for explaining a first example of application, and FIG. 3(d) showing a sectional view for explaining a second example of application.

FIG. 4 is a graph giving a schematic representation of the relation between displacement and load in metal electrodes when mounting a semiconductor device according to the present invention.

FIG. 5 shows enlarged schematic views for explaining examples of the application of external connection electrodes of a semiconductor device in the present invention, FIG. 5(a) showing an external view of external connection electrodes in which the side surface has an upside-down T shape, and FIG. 5(b) showing an external view of external connection electrodes in which the upper surface has a bent portion.

FIG. 6 gives an enlarged schematic representation of the bottom surface to explain the arrangement of external connection electrodes of the semiconductor device in the present invention.

FIG. 7 gives an enlarged schematic representation of the bottom surface illustrating the direction of extension of protruding portions of the external connection electrodes of the semiconductor device in the present invention.

FIG. 8 shows enlarged schematic views for explaining the method of fabricating a semiconductor device according to the present invention, FIG. 8(a) showing a sectional view after forming the first mask, FIG. 8(b) showing a sectional view after the first plating, FIG. 8(c) showing a sectional view after forming the second mask, FIG. 8(d) showing a sectional view after the second plating, and FIG. 8(e) showing a sectional view after removing the masks.

FIG. 9 shows enlarged schematic views for explaining an example of the application of the semiconductor device fabrication method according to the present invention, FIG. 9(a) showing a sectional view after forming the first mask, FIG. 9(b) showing a sectional view after the first plating, FIG. 9(c) showing a sectional view after forming the second mask, FIG. 9(d) showing a sectional view after the second plating, and FIG. 9(e) showing a sectional view after connecting to the semiconductor chip.

FIG. 10 shows enlarged schematic views for explaining an example of the application of the method of fabricating the semiconductor device according to the present invention, FIG. 10(a) showing a sectional view after forming the first mask, FIG. 10(b) showing a sectional view after the first plating, FIG. 10(c) showing a sectional view after forming the second mask, FIG. 10(d) showing a sectional view after the second plating, and FIG. 10(e) showing a sectional view after removing the masks.

FIG. 11 shows enlarged schematic views for explaining an embodiment of the package construction of the semiconductor device in the present invention, FIG. 11(a) showing a sectional view before mounting the semiconductor device, and FIG. 11(b) showing a sectional view after mounting the semiconductor device.

FIG. 12 shows enlarged schematic views for explaining a first example of the application of the package construction of the semiconductor device in the present invention, FIG. 12(a) showing a sectional view before mounting the semiconductor device, and FIG. 12(b) showing a sectional view after mounting the semiconductor device.

FIG. 13 shows enlarged schematic views for explaining a second example of the application of the package structure of a semiconductor device in the present invention, FIG. 13(a) showing a sectional view before mounting the semiconductor device, and FIG. 13(b) showing a sectional view after mounting the semiconductor device.

FIG. 14 shows enlarged schematic views for explaining a third example of the application of the package structure of a semiconductor device in the present invention, FIG. 13(a) showing a sectional view before mounting the semiconductor device, and FIG. 13(b) showing a sectional view after mounting the semiconductor device.

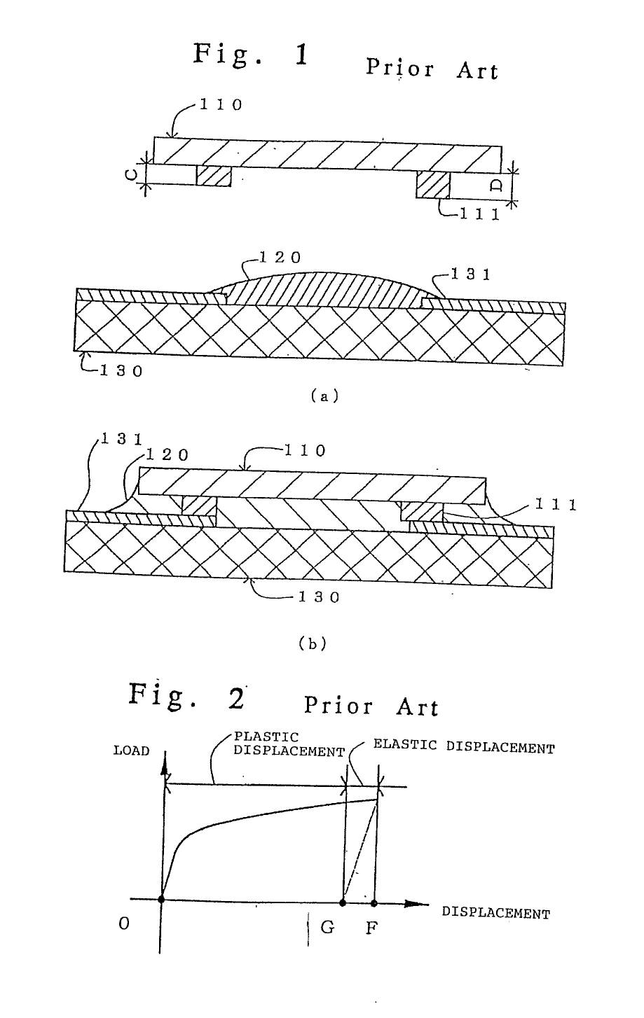

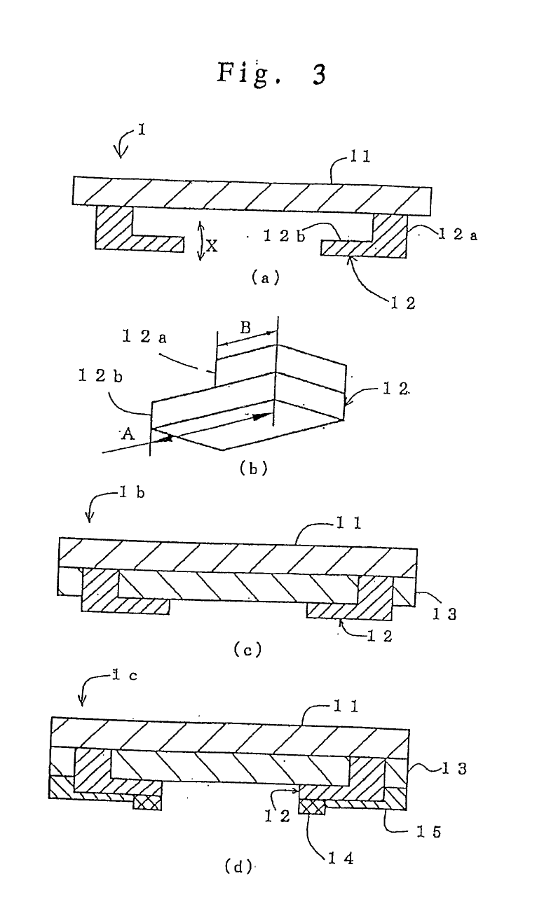

### DETAILED DESCRIPTION OF THE PREFERRED EMBODIMENTS

Explanations regarding embodiments of the semiconductor device according to the present invention, a method of fabricating the semiconductor device, a package construction of the semiconductor device, and a method of mounting the semiconductor device are each presented hereinbelow with reference to the accompanying drawings.

[Semiconductor Device]

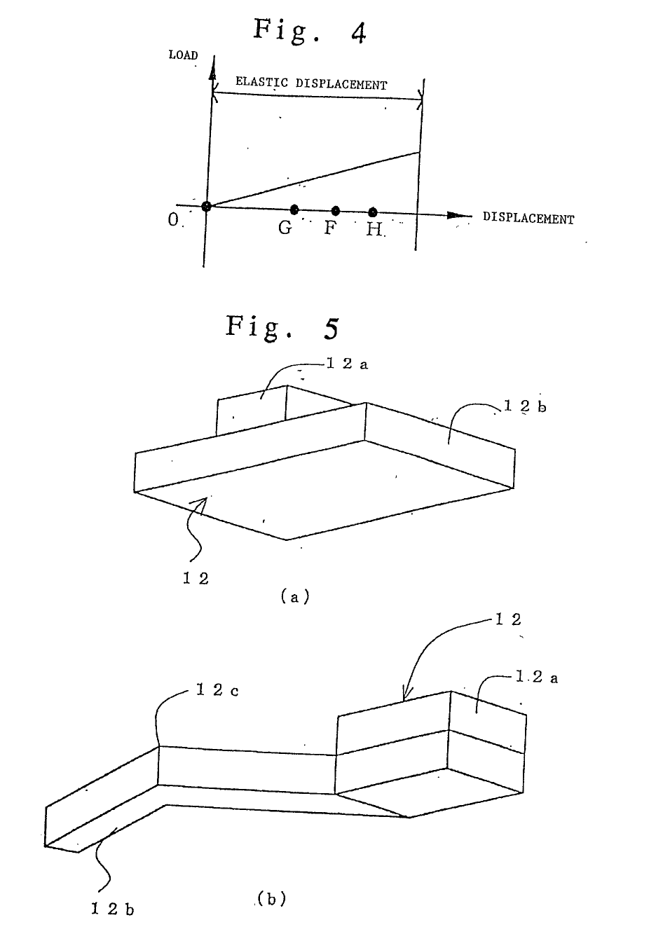

First, regarding an embodiment of the semiconductor device of the present invention, we refer to FIG. 3 in which are shown enlarged schematic views for explaining an embodiment of the semiconductor device in the present invention, FIG. 3(a) showing a sectional view, FIG. 3(b) showing an outside view of the external connection electrodes, FIG. 3(c) showing a sectional view for explaining a first example of application, and FIG. 3(d) a sectional view for explaining a second example of application.

In FIG. 3(a), 1 is a semiconductor device of a construction having external connection electrodes 12 that contact land electrodes (not shown in the figure) while maintaining an elastically deformed state in the direction shown by arrow X in the figure, external connection electrodes 12 being formed by lamination.

In this case, semiconductor device 1 contacts and electrically connects with land electrodes in a state in which external connection electrodes 12 maintain elastic deformation.

In other words, external connection electrodes 12 can absorb variations in the coplanarity of each of the external connection electrodes and land electrodes within their elastic displacement, and as a result, the external force for pressing the semiconductor device against the mounting body when mounting the semiconductor device can be reduced and the danger of damage to the semiconductor device and mounting body can be eliminated.

Semiconductor device 1 that has been mounted on a mounting body by way of an adhesive undergoes an increase in temperature when conducting electricity, whereby the bonding resin, which has a linear expansion coefficient that is greater than that of the external connection electrodes, undergoes thermal expansion, and the distance between the land electrodes and the electrodes of the semiconductor chip widens. However, because the external connection electrodes store a still greater elastic displacement and can absorb the above-described increase in distance by means of elastic displacement, the external connection electrodes and land electrodes can maintain contact, with the result that the reliability of electrical connection can be improved.

In addition, because external connection electrodes 12 are formed by lamination as will be explained hereinbelow, these electrodes are not only amenable to miniaturization, but can be efficiently manufactured with superior dimensional accuracy and low fabrication costs.

A metal such as gold or aluminum is normally used as the material of external connection electrodes 12.

The external connection electrodes that are formed by lamination are preferably fine external connection electrodes having a pitch of 10 μm-200 μm (the width of the external connection electrodes is normally the length of half the pitch). When the pitch is narrower than 10 μm, the semiconductor device cannot be packaged due to the difficulties posed by the positional accuracy of the land electrodes and the accuracy of mounting the semiconductor device on the mounting body (a substrate is normally used). When the pitch is greater than 200 μm, on the other hand, the external connection electrodes can be formed by TAB (tape automated bonding) leads. The external connection electrodes are more preferably fine external connection electrodes having a pitch of 40-80 μm.

In a case in which the positional accuracy of the land electrodes on the mounting body and the accuracy of mounting the semiconductor device are improved, the lower limit is no longer limited to 10 μm, and external connection electrodes having a pitch of as little as 1 μm can be manufactured, thereby enabling miniaturization of the semiconductor device and high-density packaging.

Here, external connection electrodes 12 may be formed with side surfaces having an L shape, in which case the protruding portion of external connection electrodes 12 that extends horizontally can be viewed as a beam having one fixed end and one free end. When a vertical load acts on the free end, the free end is vertically displaced such that the beam bends, and a high level of elastic displacement can be stored.

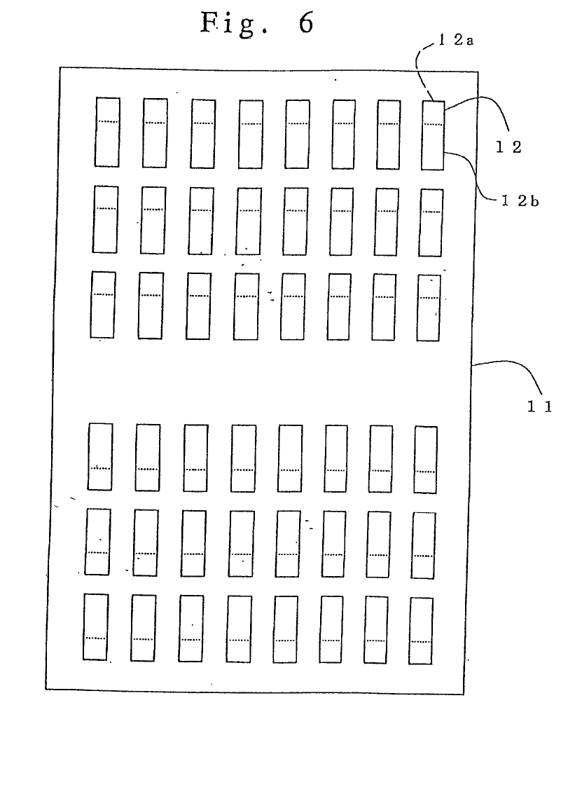

In other words, because the end portions (free ends) of external connection electrodes 12 can be greatly displaced within an elastic region, variations in the coplanarity of each of external connection electrodes 12 and variations in land electrodes (not shown in the figure) can be absorbed when mounting semiconductor device 1 by, for example, displacement OG (elastic displacement) shown in FIG. 4 without causing plastic deformation of external connection electrodes 12, whereby the force for pressing semiconductor device 1 against a mounting body such as a substrate can be reduced, and the danger of damage to semiconductor device 1 and the mounting body can be eliminated.

In a case in which the space between semiconductor device 1 and the mounting body is filled with, for example, a bonding resin, the distance between the land electrodes and the electrodes of the semiconductor chip will fluctuate when the ambient temperature changes due to the difference between the linear expansion coefficients of external connection electrodes 12 and the bonding resin. This fluctuation, however, can be absorbed by displacement FH (elastic displacement) shown in FIG. 4, and the state of connection between the external connection electrodes and the land electrodes of the mounting body can therefore be maintained and the reliability of the electrical connection can be increased.

Normally, external connection electrodes 12 are preferably formed such that horizontal length A in protruding portion 12b is 1.2-10 times horizontal length B in base portion 12a, as shown in FIG. 3(b). A large elastic displacement cannot be stored if length A is less than 1.2 times that of length B, while forming length A more than 10 times length B prevents application for large numbers of pins or for high-density packaging. External connection electrodes 12 are more preferably formed such that length A is 2-5 times length B.

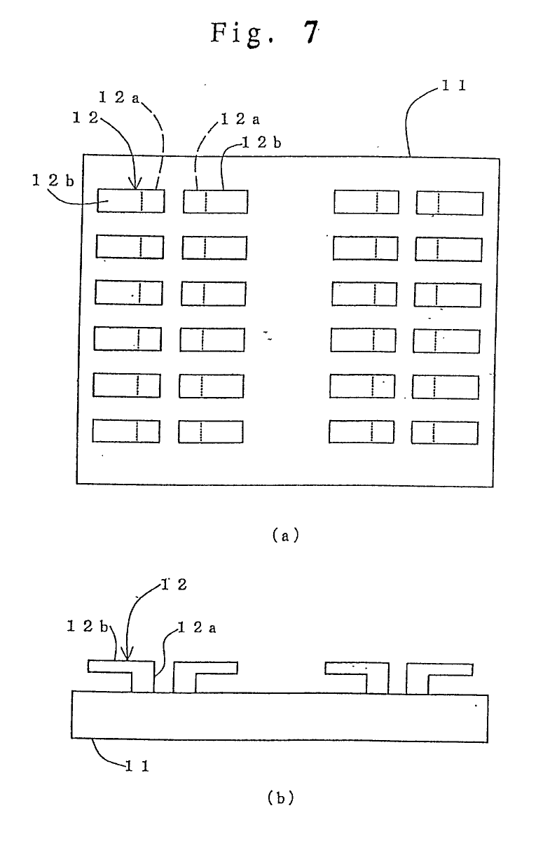

The shape of the side surfaces of external connection electrodes is not limited to the above-described shape and dimensional relationship, and length A, the thickness, and width can be freely designed to ensure the required elastic displacement. A variety of shapes can be adopted including a J shape and a hooked shape. For the purpose of increasing the reliability of electrical connections, each external connection electrode may be formed in an upside-down T shape as shown in FIG. 5(a) and a construction may be adopted in which both end portions of an external connection electrode contact a land electrode. Protruding portion 12b is not limited to a flat shape, and a form provided with ribs or a form in which plates of a differing material and/or shape are attached may also be adopted.

Alternatively, the external connection electrodes may have a shape in which angled bend 12c is formed in the shape of the upper surface as shown in FIG. 5(b). The adoption of this construction allows the external connection electrodes to store a large elastic displacement for horizontal fluctuation displacement that arises from the difference in linear expansion coefficients of the mounting body (for example, a resin substrate) and the semiconductor chip.

The shape of the upper surface of external connection electrodes is not limited to the shapes described in the foregoing description, and various shapes may be adopted including an S shape or a hooked shape according to the required elastic displacement.

Explanation next regards a first example of the application of the semiconductor device of the present invention.

(First Example of Application)

Semiconductor device 1b in the first example of application is a construction in which elastic layer 13 is formed between semiconductor chip 11 and the protruding portions 12b of external connection electrodes 12 as shown in FIG. 3(c).

When this construction is adopted, elastic layer 13 is compressed and deformed when external connection electrodes 12 undergo elastic deformation in semiconductor device 1b that is mounted, and the elastic force of elastic layer 13 is therefore added to the elastic displacement of external connection electrodes 12. As a result, the load during mounting and the elastic deformation that is stored in external connection electrodes 12 can be adjusted. The contact surface pressure between external connection electrodes 12 and bumps 22 can therefore be set at a high level, thereby enabling an improvement in the reliability of electrical connections.

Although a polyimide resin (tensile elastic modulus=approximately 4500 MPa), which allows easy film formation and has an appropriate elastic force, is ideal as the material of above-described elastic layer 13, the invention is not limited to this material, and other materials (such as epoxy resin) may of course be employed.

Explanation next regards a second example of the application of the semiconductor device of the present invention.

(Second Example of Application)

In semiconductor device 1c in the second example of application, bumps 14 are formed on external connection electrodes 12 as shown in FIG. 3(d). This construction can be employed in cases in which the formation of bumps on the land electrodes of the mounting body is difficult from the standpoint of productivity. In addition, the shape of external connection electrodes 12 can be simplified, specifically, protruding portion 12b can be formed by laminating horizontally, thereby enabling a reduction of production costs.

Bumps 14 are preferably formed on the tips of protruding portions 12b of external connection electrodes 12, whereby external connection electrodes 12 can store greater elastic deformation.

Semiconductor device 1c may also have a construction in which insulative protective film 15 is formed on the lower surface of external connection electrodes 12. This construction prevents external connection electrodes 12 from directly contacting the wiring of the mounting body, thereby preventing the occurrence of short-circuit defects and enabling easier and higher-quality packaging.

If protective film 15 is formed from an elastic material, the area in which external connection electrodes 12 contact the bonding resin is reduced and a major obstacle to the elastic deformation of external connection electrodes 12 can be eliminated.

Still further, protective film 15 can be used as a spacer for determining the height of semiconductor device 1c and the mounting body, and the elastic displacement of external connection electrodes 12 can be determined as appropriate.

Although a polyimide resin, which allows easy film formation and has an appropriate elastic force, is ideal as the material of above-described protective film 15, the invention is not limited to this material, and other materials (such as epoxy resin) may of course be employed.

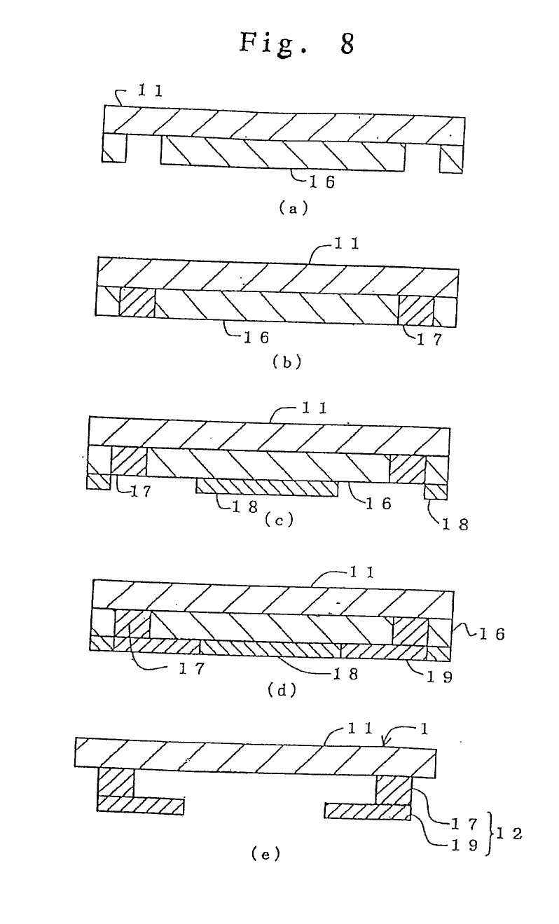

A construction may further be adopted in which external connection electrodes 12 are arranged in array form on semiconductor chip 11, as shown in FIG. 6. This construction allows application to a greater number of pins.

External connection electrodes 12 are normally arranged in an array of n×m rows (n and m being natural numbers), but other array forms may of course be adopted.

External connection electrodes 12 may have a different shape in accordance with the positions of the land electrodes of the mounting body and the characteristics of the signal lines and ground lines.

External connection electrodes 12 are not limited to a form in which the horizontal protruding portions 12b are formed extending toward the inside of the semiconductor device, and for example, the protruding portions 12b of external connection electrodes 12 that are arranged along the outside of semiconductor chip 11 may extend in an outward direction and protruding portions 12b of external connection electrodes 12 that are arranged inside may extend inward, as shown in FIG. 7. This construction enables greater distance between land electrodes and can prevent the occurrence of short-circuit defects. This construction also increases the freedom of design of the land electrodes, thereby enabling higher-density packaging of the semiconductor device.

Explanation next regards embodiments of the method of fabricating a semiconductor device in the present invention.

[Method of Fabricating a Semiconductor Device]

The method of fabricating a semiconductor device according to the present invention is a method for fabricating a semiconductor device that includes: a semiconductor chip on which electrodes have been formed; and external connection electrodes that are formed on these electrodes, and moreover, that electrically connect to land electrodes of a mounting body by contact while maintaining an elastically deformed state; and further, is a method for forming external connection electrodes on the electrodes of the semiconductor chip by lamination.

The external connection electrodes can be formed by lamination by an electroplating method, an electroless plating method, and a sputtering method. A method of fabricating a semiconductor device by the electroless plating method will be explained with reference to the accompanying figures.

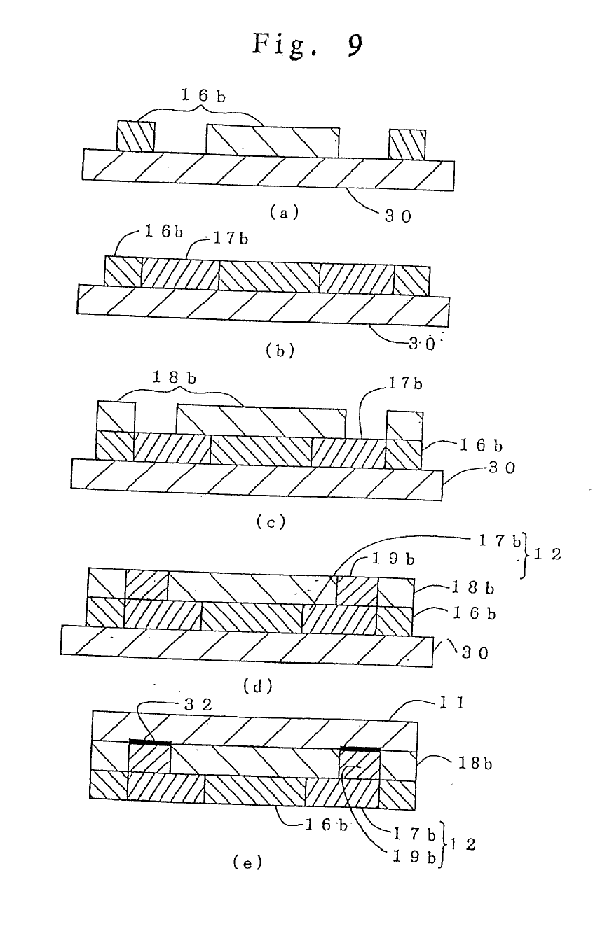

FIG. 8 shows enlarged schematic views for explaining the method of fabricating a semiconductor device according to the present invention, FIG. 8(a) showing a sectional view after forming the first mask, FIG. 8(b) showing a sectional view after the first plating, FIG. 8(c) showing a sectional view after forming the second mask, FIG. 8(d) showing a sectional view after the second plating, and FIG. 8(e) showing a sectional view after removing the masks.

In FIG. 8 (a), first mask 16 is first formed in portions other than the electrode (not shown in the figure) on the lower surface of semiconductor chip 11 (first mask formation step), following which first plating 17 is laminated as shown in FIG. 8(b) (first plating step).

The formation of first plating 17 forms the base portions 12a of the external connection electrodes by lamination.

A catalyst is adhered to the side surfaces of openings in first mask 16 and on electrodes of semiconductor chip 11 by means of a catalyst adhesion mask (not shown in the figure), whereby first plating 17 can be formed by lamination with good dimensional accuracy.

Gold, which has excellent conductivity, is normally used as the plating material, but the present invention is not limited to the use of gold, and metals such as aluminum are commonly used.

Next, in FIG. 8(c), second mask 18 is formed in portions of first mask 16 other than those areas in which horizontally protruding portions of the external connection electrodes are to be formed (second mask formation step), following which second plating 19 is formed by lamination as shown in FIG. 8(d) (second plating step).

The formation of second plating 19 forms horizontal protruding portions 12b of external connection electrodes 12.

Next, first mask 16 and second mask 17 are removed as shown in FIG. 8(e) (mask removal step), whereby external connection electrodes 12 are formed on semiconductor chip 11.

In this way, miniaturized external connection electrodes 12 can be efficiently produced with good dimensional accuracy.

When laminating second plating 19 shown in FIG. 8(d), the horizontal extending portions of the external connection electrodes can be formed by lamination by sputtering after forming second mask 18 shown in FIG. 8(c). Adopting this approach enables the laminated formation of second plating 17 with more accurate thickness.

A fabrication method may also be adopted in which a polyimide resin having elasticity is used as the material of first mask 16 and in which only second mask 18 is removed after laminating second plating 19 shown in FIG. 8(d). This method can raise productivity because it allows elastic layer 13 to be formed in the step of laminating first mask 16.

This method of fabricating a semiconductor device makes possible the efficient production of miniaturized external connection electrodes having good dimensional accuracy.

In addition, protective film 15 shown in FIG. 3(d) can be formed by the same method as second mask 18 shown in FIG. 8(c).

Although not shown in the figures, bumps on external connection electrodes 12 may be formed by methods such as plating, evaporation, sputtering, and printing.

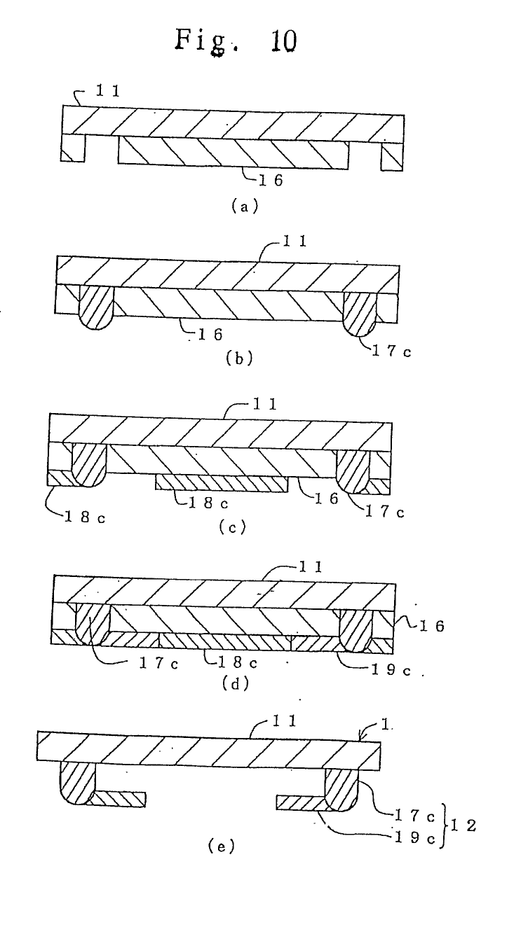

The semiconductor device in this invention is not limited to the above-described fabricating method and may be fabricated by a method in which external connection electrodes 12 are formed by lamination separate from semiconductor chip 11, and these external connection electrodes 12 are then caused to electrically connect to the electrodes of semiconductor chip 11 by means of a conductive material (specifically, a material such as conductive paste 32 or conductive adhesive), as shown in FIG. 9.

In FIG. 9(a), first mask 16b is formed according to the position and shape of protruding portion 12b of external connection electrodes 12 on laminated plate 30 composed of a material such as glass (first mask formation step), following which first plating 17b is formed by lamination as shown in FIG. 9(b) (first plating step).

The formation of first plating 17b forms by lamination the protruding portions 12b of external connection electrodes 12.

Next, in FIG. 9(c), second mask 18b is formed according to the position and shape of the base portions of external connection electrodes on first mask 16b and first plating 17b (second mask formation step), following which second plating 19b is formed by lamination as shown in FIG. 9(d) (second plating step).

The formation of second plating 19b forms base portions 12a of external connection electrodes 12.

Next, as shown in FIG. 9(e), external connection electrodes 12 that have been formed by lamination on masks 16b and 18b are electrically connected to the electrodes of semiconductor chip 11 by way of a conductive material (conductive paste 32) on base portions 12a and/or the electrodes (not shown) of semiconductor chip 11 (connection step), and finally, external connection electrodes 12 composed of first plating 17b and second plating 19b are formed on semiconductor chip 11 by removing laminated plate 30.

The adoption of this method enables miniaturized external connection electrodes to be efficiently produced with good dimensional accuracy, and further, allows the easy exchange of semiconductor chip 11.

In addition, external connection electrodes 12 can be more securely connected to the electrodes of semiconductor chip 11 by applying an adhesive to second mask 18b and then bonding semiconductor chip 11.

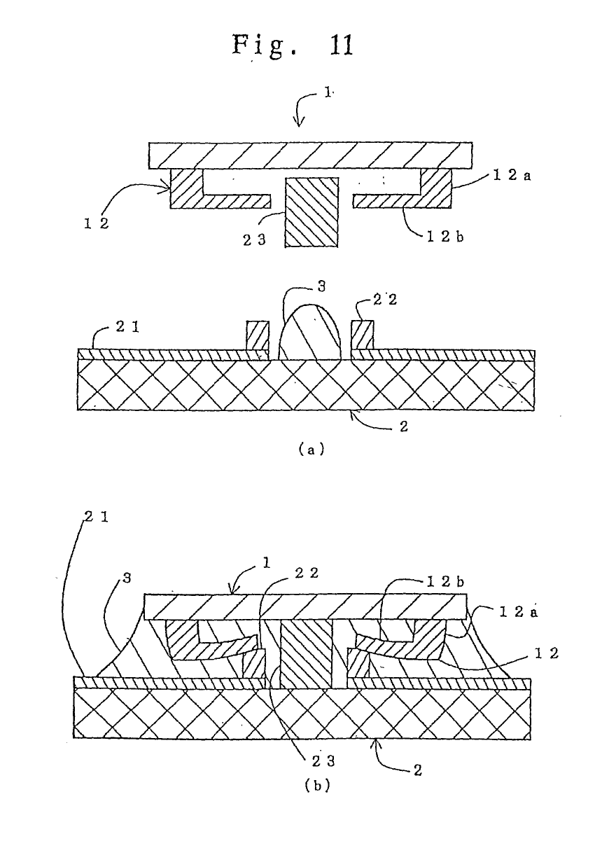

The semiconductor device in this invention can also be fabricated by an electroplating method as shown in FIG. 10.

First, as shown in FIG. 10(a), first mask 16 is formed on portions other than the electrodes (not shown in the figure) on the lower surface of semiconductor chip 11 (first mask formation step), following which first plating 17c is formed by lamination as shown in FIG. 10(b) (first plating step).

Here, first plating 17c having ends that protrude in a spherical shape, this first plating 17c constituting base portions 12a of external connection electrodes 12, is formed by an electroplating method.

Next, as shown in FIG. 10(c), second mask 18c is formed on first mask 16 in portions other than the areas in which the horizontally extending portions in external connection electrodes are to be formed (second mask formation step), following which second plating 19c is formed by lamination as shown in FIG. 10(d) (second plating step).

Here, the formation of second plating 19c forms horizontal protruding portion 12b of external connection electrodes 12.

Next, as shown in FIG. 10(e), first mask 16 and second mask 18c are removed (mask removal step) to complete the formation of external connection electrodes 12 of semiconductor chip 11.

In this way, miniaturized external connection electrodes 12 can be efficiently produced with good dimensional accuracy by an electroplating method. In addition, by forming the tip portions of first plating 17c in the shape of hemispheres that protrude from first mask 16, and further, forming second mask 18c so as to partially cover the curved surface of first plating 17c, external connection electrodes having L-shaped side surfaces can be formed by lamination.

Explanation next regards an embodiment of the package structure of a semiconductor device in the present invention.

[Semiconductor Device Package Construction]

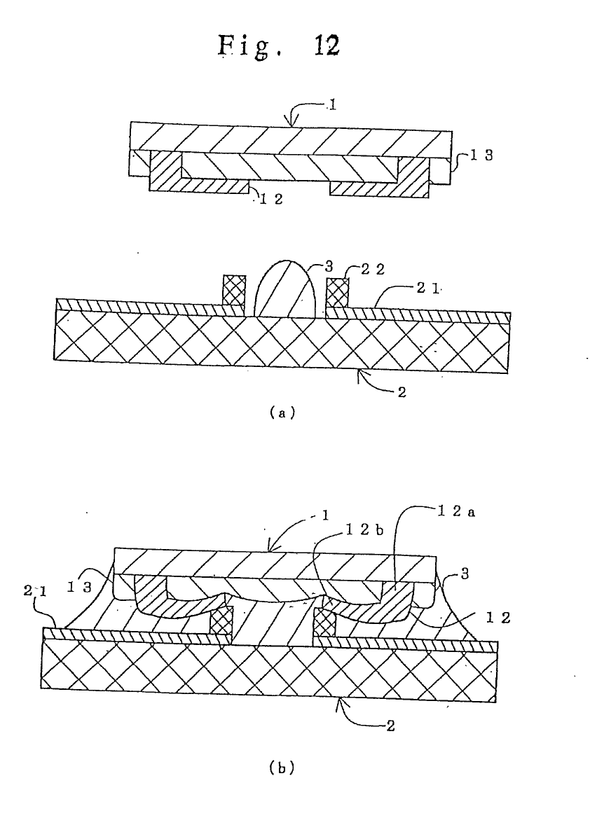

FIG. 11 shows enlarged schematic views for explaining an embodiment of the package construction of the semiconductor device in the present invention, FIG. 11(a) showing a sectional view before mounting the semiconductor device, and FIG. 11(b) showing a sectional view after mounting the semiconductor device.

In FIG. 11(b), the package construction of the semiconductor device is a package construction in which semiconductor device 1 is mounted on substrate 2, which is the mounting body; this being a construction in which external connection electrodes 12 of semiconductor device 1 are electrically connected to substrate wiring 21, substrate wiring 21 being land electrodes that have been formed on substrate 2, and in which semiconductor chip 11 is bonded to substrate 2 by bonding resin 3.

In addition, external connection electrodes 12 contact substrate wiring 21 via bumps 22 in a state in which protruding portions 12b and base portions 12a maintain elastic deformation, whereby: variations in the coplanarity of the upper surfaces of external connection electrodes 12 and bumps 22 are absorbed; the external force with which semiconductor device 1 is pressed against substrate 2 when mounting semiconductor device 1 can be reduced; and the danger of damage to semiconductor device 1 and substrate 2 can be eliminated.

Bumps 22 are preferably formed on substrate wiring 21, in which case external connection electrodes can be formed by lamination horizontally and external connection electrodes having inclined end portions need not be laminated, thereby allowing an improvement in productivity.

Semiconductor device 1 is bonded to substrate 2 by way of bonding resin 3, and changes in the ambient temperature may therefore cause fluctuation in the distance between bumps 22 and the electrodes of semiconductor chip 11 due to the difference in linear expansion coefficients of bonding resin 3 and external connection electrodes 12. However, this fluctuation displacement is absorbed by the elastic displacement of external connection electrodes 12, and as a result, external connection electrodes 12 and bumps 22 maintain contact and the reliability of electrical connection can be improved.

Joining that employs solder paste is technically difficult for fine-structure external connection electrodes 12 having a pitch of 100 μm or less, but miniaturization of semiconductor device 1 and higher-density packaging can be realized without causing damage to semiconductor device 1 and substrate 2 by establishing electrical connections by bringing external connection electrodes 12 into contact with bumps 22 and mechanically joining semiconductor chip 11 by means of bonding resin 3.

A construction may also be adopted in which spacer 23 is provided between semiconductor device 1 and substrate 2. This construction enables easy and accurate setting of the position in the direction of height of semiconductor device 1, thereby enabling appropriate setting of the elastic displacement of external connection electrodes 12.

Spacer 23 is not limited to this form, and for example, markers may be formed that are arranged in each corner of semiconductor device 1 for positioning semiconductor device 1. Alternatively, spacer 23 may be a construction that is attached to semiconductor device 1 or substrate 2 in advance.

(First Example of Application of the Package Construction of a Semiconductor Device)

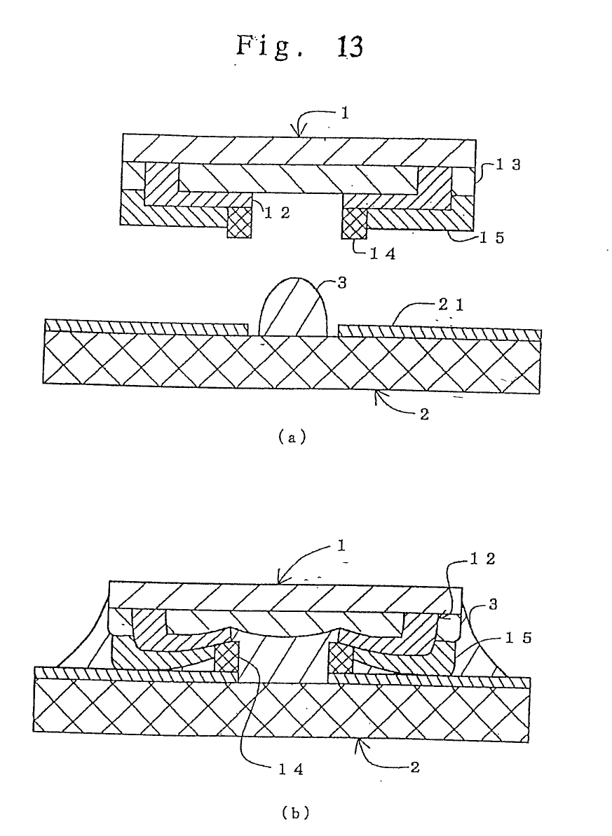

The package construction of a semiconductor device in the present invention is not limited to the above-described construction, and may, for example, employ semiconductor device 1 having elastic layer 13, as shown in FIG. 12. When this construction is adopted, elastic layer 13 is also deformed when external connection electrodes 12 undergo elastic deformation in semiconductor device 1. The elastic force of elastic layer 13 is therefore added to the elastic force of external connection electrodes 12, thereby enabling adjustment of both the load when mounting and the elastic deformation that is stored in external connection electrodes 12.

The contact surface pressure between external connection electrodes 12 and bumps 22 can thus be set to a high level to enable an improvement in the reliability of electrical connection.

(Second Example of Application of the Package Construction of a Semiconductor Device)

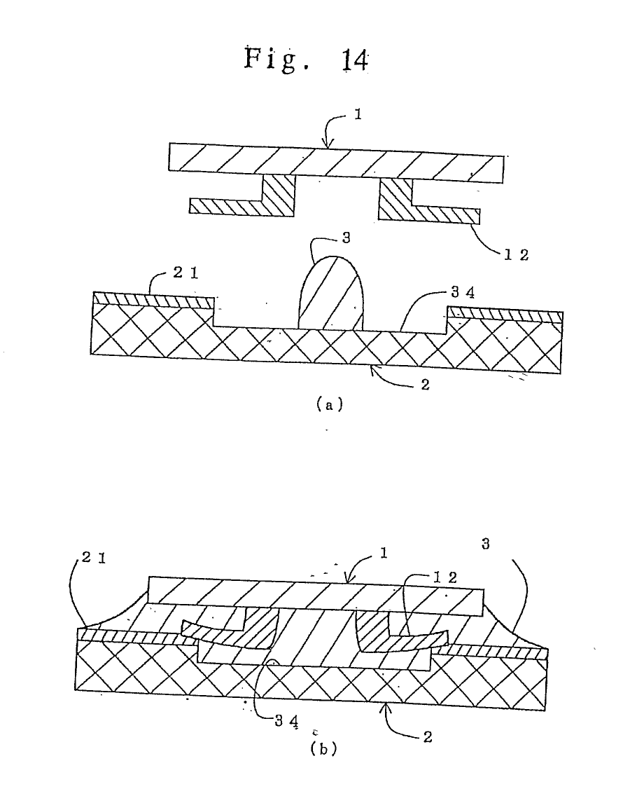

Alternatively, semiconductor device 1 having elastic layer 13, bumps 14, and protective film 15 may also be used, as shown in FIG. 13. In this package construction, bumps are not provided on the substrate wiring because bumps 14 have been formed on external connection electrodes 12.

The adoption of this construction results in a structure in which external connection electrodes 12 make little contact with bonding resin 3 due to protective film 15 and therefore readily undergo elastic deformation without being adversely affected by bonding resin 3 during fluctuation displacement caused by increase in the temperature of the semiconductor device. As a result, a more reliable electrical connection to substrate wiring 21 can be achieved and connection reliability can be improved.

In addition, the presence of protective film 15 eliminates the danger of contact between external connection electrodes 12 and substrate wiring 21, and mounting is thus facilitated and reliability can be increased regarding short-circuit defects of the semiconductor device.

(Third Example of Application of the Package Construction of a Semiconductor Device)

The package structure of a semiconductor device in the present invention has a wide variety of applications, and for example, a construction may be adopted in which protruding portions 12b of external connection electrodes 12 extend outward and cavity 34 is formed between the opposing substrate wiring 21 as shown in FIG. 14. The adoption of this construction allows external connection electrodes 12 to contact substrate wiring 21 while maintaining elastic deformation without providing bumps on external connection electrodes 12 or substrate wiring 21.

Explanation next regards embodiments of the method of mounting a semiconductor device in the present invention.

[Semiconductor Device Mounting Method]

The method of mounting a semiconductor device in the present invention is a method for mounting semiconductor device 1 on substrate 2, this semiconductor device 1 including external connection electrodes 12 that electrically connect with substrate wiring 21 of substrate 2 by means of contact while maintaining an elastically deformed state as shown in FIG. 11(a). The method first involves the application of bonding resin 3 to substrate 2 in advance to bond semiconductor device 1 to substrate 2 (bonding resin application step).

Bonding resin 3 is next cured while, for example, applying external force (load) to semiconductor device 1 such that external connection electrodes 12 are in contact with substrate wiring 21 while maintaining an elastically deformed state (bonding step).

In this step, when semiconductor device 1 is aligned such that external connection electrodes 12 confront bumps 22, placed facedown, and then pressed against substrate 2, bonding resin 3 is compressed and spread, and external connection electrodes 12 contact and electrically connect with bumps 22 while undergoing elastic deformation.

Adopting this method enables external connection electrodes 12 and substrate wiring 21 to be connected within the range of the elastic displacement of external connection electrodes 12, i.e., under low load, thereby eliminating the danger of damage to semiconductor device 1 and substrate 2, and further, raising the reliability of electrical connection.

When pressed against substrate 2, semiconductor device 1 contacts bonding resin 3, and semiconductor device 1 is secured to substrate 2 by allowing bonding resin 3 to harden in this state.

The number of times of supplying bonding resin 3 is not limited to one, and the method may, for example, include temporary bonding followed by a short-circuit check, following which only packages that have passed inspection undergo permanent bonding.

Furthermore, the application of bonding resin 3 is not limited to substrate 2, and bonding resin 3 may be applied to semiconductor chip 11 or to both substrate 2 and semiconductor chip 11.

The force of contraction that occurs when bonding resin 3 cures may be used when external force is applied to semiconductor device 1, in which case the pressing apparatus that presses semiconductor device 1 against substrate 2 may be of smaller scale, thereby allowing a reduction in the cost of the pressing apparatus.

The present invention is therefore effective as a method of mounting a semiconductor device, and through the use of this mounting method, a semiconductor device that includes external connection electrodes that are capable of storing a large elastic displacement can be packaged by a method that features excellent productivity and product quality.

While preferred embodiments of the present invention have been described using specific terms, such description is for illustrative purposes only, and it is to be understood that changes and variations may be made without departing from the spirit or scope of the following claims.

What is claimed is:

1. A semiconductor device comprising:
a semiconductor chip on which electrodes have been formed; and
external connection electrodes that are electrically connected to land electrodes of a mounting body;
wherein said external connection electrodes contact said land electrodes while maintaining an elastically deformed state.

2. A semiconductor device according to claim 1, wherein said external connection electrodes are formed by lamination on electrodes of said semiconductor chip.

3. A semiconductor device according to claim 1, wherein the side surfaces of said external connection electrodes have an L-shape.

4. A semiconductor device according to claim 1, wherein the upper surfaces of said external connection electrodes have a bent portion.

5. A semiconductor device according to claim 1, wherein bumps are formed on said external connection electrodes.

6. A semiconductor device according to claim 1, wherein an elastic layer is formed between said external connection electrodes and said semiconductor chip.

7. A semiconductor device according to claim 1, wherein a protective film having an insulative property is formed on the lower surface of said external connection electrodes.

8. A semiconductor device according to claim 1, wherein said external connection electrodes are arranged as an array.

9. A semiconductor device according to claim 1, wherein a portion or all of the plurality of said external connection electrodes extend either toward the inside or toward the outside of said semiconductor chip.

10. A method of fabricating a semiconductor device, comprising steps of:
forming electrodes on a semiconductor chip; and
forming, on the electrodes of said semiconductor chip, external connection electrodes that electrically connect to land electrodes of a mounting body on which said semiconductor device is mounted, said external connection electrodes establishing electrical connection by contact while maintaining an elastically deformed state.

11. A method of fabricating a semiconductor device according to claim 10, wherein said step of forming said external connection electrodes on electrodes of said semiconductor chip is a step of forming said external connection electrodes by lamination on electrodes of said semiconductor chip.

12. A method of fabricating a semiconductor device according to claim 10, wherein said step of forming said external connection electrodes on electrodes of said semiconductor chip comprises steps of:
forming said external connection electrodes by lamination on a mask of said semiconductor chip, and electrically connecting said external connection electrodes to electrodes of said semiconductor chip by way of a conductive material.

13. A semiconductor device package construction, comprising:
a mounting body on which land electrodes are formed;
a semiconductor device that includes external connection electrodes that are formed by lamination on a semiconductor chip and that contact said land electrodes while maintaining an elastically deformed state; and
a bonding resin for bonding said semiconductor device to said mounting body.

14. A semiconductor device package construction according to claim 13, wherein bumps are formed on either said land electrodes or said external connection electrodes.

15. A semiconductor device package construction according to claim 13, wherein
a spacer for positioning in the direction of height of said semiconductor chip is provided between said semiconductor chip and said mounting body.

16. A method of mounting a semiconductor device comprising steps of:
supplying in advance to a mounting body having land electrodes and/or a semiconductor device having external connection electrodes, a bonding resin for bonding said semiconductor device to said mounting body; and
curing said bonding resin such that said external connection electrodes contact said land electrodes while maintaining an elastically deformed state.

17. A method of mounting a semiconductor device according to claim 16, wherein the force of contraction that occurs when said bonding resin cures is used to maintain said elastically deformed state.
